(19) United States
(12) Patent Application Publication
(10) Pub. No.: US 2025/0217045 A1
(43) Pub. Date: Jul. 3, 2025

(54) MEMORY SYSTEM AND METHOD OF OPERATING THE SAME

(71) Applicant: SAMSUNG ELECTRONICS CO., LTD., Suwon-si (KR)

(72) Inventors: Soojun IM, Suwon-si (KR); Nam Wook Kang, Suwon-si (KR); Chanha Kim, Suwon-si (KR)

(73) Assignee: SAMSUNG ELECTRONICS CO., LTD., Suwon-si (KR)

(21) Appl. No.: 18/974,182

(22) Filed: Dec. 9, 2024

(30) Foreign Application Priority Data
Jan. 2, 2024 (KR) 10-2024-0000536

(51) Int. Cl. G06F 3/06

(52) U.S. Cl. CPC G06F 3/0619; G06F 3/0659; G06F 3/0673

(57) ABSTRACT

A memory system includes a memory device including a plurality of blocks, and a memory controller configured to control the memory device. The plurality of blocks include a first block including a first sub-block having a first size and a second sub-block having a second size different from the first size, and a second block including a third sub-block having a third size and a fourth sub-block having a fourth size different from the third size. The first size is equal to the third size. The first sub-block and the third sub-block constitute a first super sub-block. The second size is equal to the fourth size. The second sub-block and the fourth sub-block constitute a second super sub-block. The memory controller is further configured to perform a reliability protection operation on the memory device in units of sub-blocks or super sub-blocks.

### CROSS-REFERENCE TO RELATED APPLICATIONS

This application claims benefit of priority under 35 U.S.C. § 119 to Korean Patent Application No. 10-2024-0000536, filed on Jan. 2, 2024, in the Korean Intellectual Property Office, the disclosure of which is incorporated by reference herein in its entirety.

### BACKGROUND

### 1. Field

The present disclosure relates generally to a memory system, and more particularly, to a memory system with reliability defense management and a method of operating the same.

### 2. Description of Related Art

Memory devices may be used to store data and may be classified into volatile memory devices and nonvolatile memory devices. A flash memory device, which may be an example of a nonvolatile memory device, may be used in mobile phones (e.g., smart phones), digital cameras, portable computer devices, stationary computer devices, or other devices. As demand for data storage capacity in electronic devices has increased in recent years, the capacity of flash memory devices has also increased.

Flash memory devices are categorized as nonvolatile memory devices. However, flash memory devices may lose their stored data due to various factors such as, but not limited to, temperature, read disturbance (read disturb), program disturbance (program/write disturb), charge loss, or the like. Accordingly, reliability defense operations may be needed to ensure the reliability of data stored in flash memory devices. However, as the capacity of flash memory devices increases, the time required to perform such reliability defense operations may also increase, degrading the performance of the flash memory devices.

Thus, there exists a need for further improvements in memory systems, as the need for increased capacity may be constrained by performance degradation due to performance of reliability defense operations. Improvements are presented herein. These improvements may also be applicable to other storage technologies and the storage standards that employ these technologies.

### SUMMARY

One or more example embodiments of the present disclosure provide a memory system for efficiently performing a reliability defense operation.

According to an aspect of the present disclosure, a memory system includes a memory device including a plurality of blocks, and a memory controller configured to control the memory device. The plurality of blocks include a first block including a first sub-block having a first size and a second sub-block having a second size different from the first size, and a second block including a third sub-block having a third size and a fourth sub-block having a fourth size different from the third size. The first size of the first sub-block is equal to the third size of the third sub-block. The first sub-block and the third sub-block constitute a first super sub-block. The second size of the second sub-block is equal to the fourth size of the fourth sub-block. The second sub-block and the fourth sub-block constitute a second super sub-block. The memory controller is further configured to perform a reliability protection operation on the memory device in units of sub-blocks or super sub-blocks.

According to an aspect of the present disclosure, a memory device includes a memory cell array including a plurality of blocks storing data, and a control logic configured to control the memory cell array. The plurality of blocks include a first block including a first sub-block having a first size and a second sub-block having a second size different from the first size, and a second block including a third sub-block having a third size and a fourth sub-block having a fourth size different from a size of the third sub-block. The first size of the first sub-block is equal to the third size of the third sub-block. The first sub-block and the third sub-block constitute a first super sub-block. The second size of the second sub-block is equal to the fourth size of the fourth sub-block. The second sub-block and the fourth sub-block constitute a second super sub-block. The control logic is further configured to control the memory cell array to perform at least one of a read reclaim operation, an active reclaim operation, or a dummy program operation in units of sub-blocks or super sub-blocks.

According to an aspect of the present disclosure, a method of operating a memory system including a plurality of blocks includes selecting a first sub-block for which a reclaim operation is requested, from among sub-blocks included in each of the plurality of blocks, as a source sub-block, allocating a second sub-block having a same size as the source sub-block and being in an empty state, from among the sub-blocks included in each of the plurality of blocks, as a destination sub-block, and moving valid data stored in the source sub-block to the destination sub-block in units of sub-blocks.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of the present disclosure may be more clearly understood from the following description, taken in conjunction with the accompanying drawings, in which:

FIG. 1 is a block diagram illustrating a memory system, according to an embodiment;

FIG. 2 is a diagram illustrating an example of a software layer of the memory system of FIG. 1, according to an embodiment;

FIG. 3 is a diagram illustrating an example of a memory controller of FIG. 1, according to an embodiment;

FIG. 4 is a block diagram illustrating an example of a memory device of FIG. 1, according to an embodiment;

FIGS. 5A to 5D are diagrams illustrating an example of super block, block, super sub-block, and sub-block included in the memory cell array of FIG. 4, according to an embodiment;

FIGS. 6A to 6D are diagrams illustrating a read reclaim operation, according to an embodiment;

FIG. 7 is a flowchart illustrating a read reclaim operation, according to an embodiment;

FIGS. 8A to 8C are diagrams illustrating an active reclaim operation, according to an embodiment;

FIGS. 9A to 9E are diagrams illustrating an active reclaim operation, according to an embodiment;

FIG. 10 is a flowchart illustrating an active reclaim operation, according to an embodiment;

FIG. 11 is a flowchart illustrating an active reclaim operation performed using sub-blocks in a super block, according to an embodiment;

FIG. 12 is a flowchart illustrating an active reclaim operation performed using a free sub-block pool, according to an embodiment;

FIGS. 13A and 13B are diagrams illustrating a dummy program operation, according to an embodiment; and

FIG. 14 is a flowchart illustrating an operation of performing processing for reuse of a super sub-block, according to an embodiment.

### DETAILED DESCRIPTION

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” 6:27hird” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

The embodiments herein may be described and illustrated in terms of blocks, as shown in the drawings, which carry out a described function or functions. These blocks, which may be referred to herein as units or modules or the like, or by names such as device, logic, circuit, controller, counter, comparator, generator, converter, or the like, may be physically implemented by analog and/or digital circuits including one or more of a logic gate, an integrated circuit, a microprocessor, a microcontroller, a memory circuit, a passive electronic component, an active electronic component, an optical component, and the like.

In the present disclosure, the articles “a” and “an” are intended to include one or more items, and may be used interchangeably with “one or more.” Where only one item is intended, the term “one” or similar language is used. For example, the term “a processor” may refer to either a single processor or multiple processors. When a processor is described as carrying out an operation and the processor is referred to perform an additional operation, the multiple operations may be executed by either a single processor or any one or a combination of multiple processors.

Hereinafter, various embodiments of the present disclosure are described with reference to the accompanying drawings.

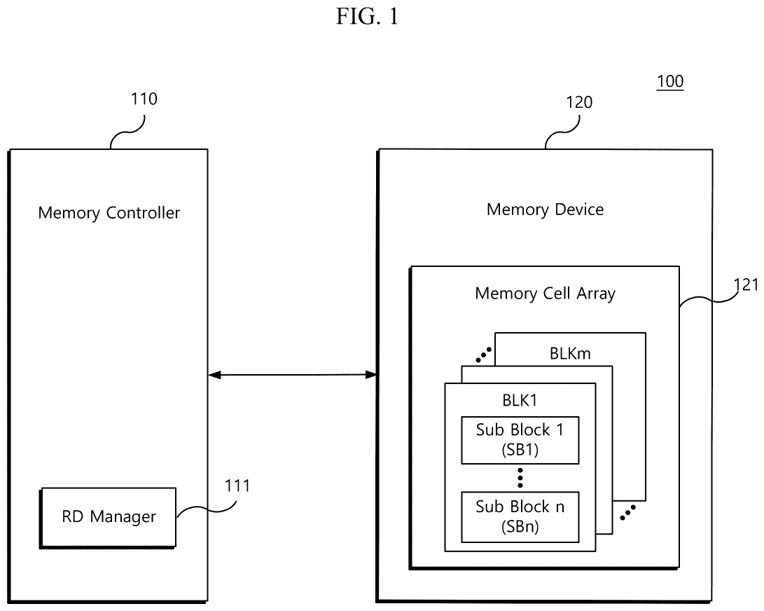

FIG. 1 is a block diagram illustrating a memory system 100, according to an example embodiment.

The memory system 100, according to an example embodiment, may include a plurality of blocks, and each of the plurality of blocks may include a plurality of sub-blocks. In an example embodiment, the plurality of sub-blocks may have different sizes. The memory system 100, according to an example embodiment, may perform a reliability defense operation in units of sub-blocks or super sub-blocks. Accordingly, an improved reliability defense operation may be provided, when compared to related memory systems.

Referring to FIG. 1, the memory system 100 may include a memory controller 110 and a memory device 120.

The memory system 100 may be and/or may include an internal storage device embedded in an electronic device. For example, the memory system 100 may be and/or may include a solid-state drive (SSD), an embedded universal flash storage (UFS) storage device, an embedded multimedia card (eMMC), or the like.

Alternatively, the memory system 100 may be and/or may include an external storage device that may be attached to and/or detached from an electronic device. For example, the memory system 100 may be and/or may include, but not be limited to, a UFS memory card, a compact flash (CF) card, a secure digital (SD) card, a micro-secure digital (Micro-SD) card, a mini-secure digital (Mini-SD) card, an extreme digital (xD) card, or a memory stick.

However, these are merely non-limiting examples, and the present disclosure is not limited in this regard. For example, the memory system 100 may also be and/or include a personal computer (PC), a data server, a network-attached storage (NAS), an Internet of Things (IoT) device, or a portable electronic device.

The memory controller 110 may control the memory device 120 based on a request of an external device (e.g. a host). For example, the memory controller 110 may transmit an address and a command to the memory device 120 based on the request of the external device. The memory controller 110 may exchange data with the memory device 120 based on the request of the external device.

The memory device 120 may store data and/or output stored data under the control of the memory controller 110. For example, the memory device 120 may be and/or may include a memory device including, but not being limited to, a NAND flash memory. However, this is a non-limiting example, and the present disclosure is not limited thereto. Alternatively or additionally, the memory device 120 may be and/or may include a memory device including nonvolatile memory elements such as, but not limited to, a NOR flash memory, a magnetoresistive random access memory (MRAM), a parallel random access memory (PRAM), an resistive random access memory (ReRAM), an ferroelectric random access memory (FRAM). Alternatively or additionally, the memory device 120 may be and/or may include a memory device including volatile memory elements such as, but not limited to, a dynamic random access memory (DRAM).

The memory device 120 may include a memory cell array 121, and the memory cell array 121 may include a plurality of blocks (e.g., a first block BLK1 to an m-th block BLKm, where m is a positive integer greater than zero (0)). Each of the plurality of blocks BLK1 to BLKm may include a plurality of memory cells. Each of the plurality of memory cells may be a single-level cell (SLC) storing one (1) bit of data or a multilevel cell (MLC) storing at least two (2) bits of data.

Each of the plurality of blocks BLK1 to BLKm may include a plurality of sub-blocks (e.g., a first sub-block SB1 to an n-th sub-block SBn, where n is a positive integer greater than zero (0)). As used herein, the term sub-block may refer to a minimum unit on which an erase operation may be performed. For example, the memory device 120 may perform an erase operation on a sub-block unit. However, the present disclosure is not limited in this regard. For example, the memory device 120 may also perform an erase operation on a block unit according to example embodiments.

Each of the plurality of blocks may have the same size. According to an example embodiment, a plurality of blocks may constitute a super block. A block or a super block may be used as a data management unit of a normal input/output (I/O) operation such as a write operation, a read operation, or the like.

Each of the plurality of sub-blocks SB1 to SBn may have a different size. For example, due to the characteristics of a physical structure of each block, each of the plurality of sub-blocks SB1 to SBn may have a different size. As another example, in a process of dynamically setting a plurality of sub-blocks SB1 to SBn in each block, each of the plurality of sub-blocks SB1 to SBn may be set to have a different size. However, the present disclosure is not limited in this regard. For example, the plurality of sub-blocks SB1 to SBn may be implemented to have the same size according to example embodiments.

According to an example embodiment, a super sub-block may be configured using sub-blocks having the same size, among sub-blocks having different sizes. A sub-block or a super sub-block may be used as a data management unit for the reliability defense operation described below.

In an example embodiment, the memory controller 110 may include a reliability defense (RD) manager 111. The reliability defense manager 111 may perform various operations to ensure the reliability of data stored in the memory device 120.

In an example embodiment, the reliability defense manager 111 may control the memory device 120 to perform a read reclaim operation. For example, when a certain page contains more than a reference number of error bits due to read disturb, the reliability defense manager 111 may control the memory device 120 to perform a read reclaim operation.

Alternatively or additionally, in an example embodiment, the reliability defense manager 111 may control the memory device 120 to perform an active reclaim operation. For example, when a write operation is interrupted due to an exceptional situation such as, but not limited to, a sudden power-off (SPO) during a write operation, the reliability defense manager 111 may control the memory device 120 to perform an active reclaim operation.

Alternatively or additionally, in an example embodiment, the reliability defense manager 111 may control the memory device 120 to perform a dummy program operation. For example, when an erase operation is performed to reuse a sub-block including invalid data, the reliability defense manager 111 may perform a dummy program operation to program dummy data in an empty space of the sub-block. Accordingly, an erase program interval (EPI) may be maintained within a certain interval.

In an example embodiment, the memory device 120 may perform a reliability defense operation, such as, but not limited to, a read reclaim operation, an active reclaim operation, or a dummy program operation, in response to a request from the reliability defense manager 111. In an example embodiment, the reliability defense operation may be performed in units of sub-blocks or super sub-blocks. The super sub-block may be a management unit including a plurality of sub-blocks.

In a case of a normal I/O operation, in which data is input/output between the memory device 120 and the memory controller 110 (e.g., a write operation or a read operation), the memory controller 110, according to an example embodiment, may control the memory device 120 such that the normal I/O operation is performed in units of blocks or super blocks. By performing the normal I/O operation in units of blocks or super blocks having a fixed size, the data stored in the memory device 120 may be effectively managed.

In addition, in the case of a reliability defense operation (e.g., a read reclaim operation, an active reclaim operation, or a dummy program operation), the memory controller 110, according to an example embodiment, may control the memory device 120 such that the reliability defense operation is performed in units of sub-blocks or super sub-blocks. By performing the reliability defense operation in units of sub-blocks or super sub-blocks, the amount of data to be processed to perform the reliability defense operation may be reduced. As a result, the performance of the reliability defense operation may be improved, when compared to related memory systems.

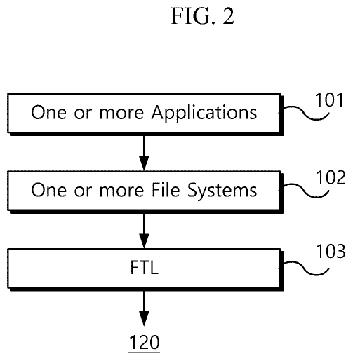

FIG. 2 is a diagram illustrating an example of a software layer of the memory system 100 of FIG. 1.

Referring to FIGS. 1 and 2, the software layer of the memory system 100 may include an applications 101, a file systems 102, and a flash translation layer (FTL) 103. For example, the application 101 and the file system 102 may be included in an external device (e.g. a host) and/or may be driven by an external device.

The application 101 may include various programs running on an operating system (OS) of an external device. For example, the application 101 may include various programs such as, but not limited to, a word processor, a video player, or a web browser.

The file system 102 may serve to organize files or data used by the application 101. For example, the file system 102 may provide an address of a file or data. For example, the address may be a logical address organized or managed by an external device.

The flash translation layer (FTL) 103 may provide an interface between the external device and the memory device 120 such that the memory device 120 may be used efficiently. For example, the flash translation layer 130 may perform an operation of converting a logical address, provided from the external device, into a physical address available in the memory device 120. For example, the flash translation layer 130 may manage the above-mentioned address translation operation through a mapping table.

In an example embodiment, the reliability defense manager 111 may be included in the flash translation layer 103. The flash translation layer 103 may control the memory device 120 to perform a reliability defense operation, such as, but not limited to, a read reclaim operation, an active reclaim operation, or a dummy program operation, in units of sub-blocks or super sub-blocks.

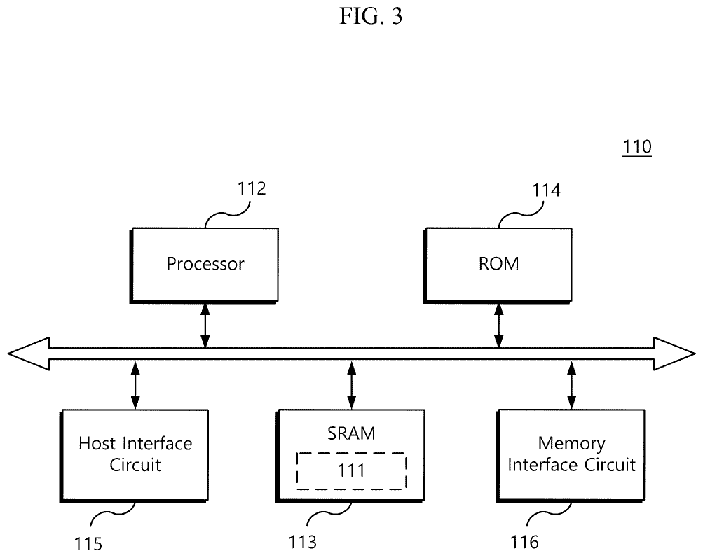

FIG. 3 is a diagram illustrating an example of the memory controller 110 of FIG. 1, according to an embodiment.

Referring to FIGS. 1 and 3, the memory controller 110 may include a reliability defense manager 111, a processor 112, a static random access memory (SRAM) 113, a read-only memory (ROM) 114, a host interface circuit 115, and a memory interface circuit 116.

The processor 112 may control the overall operation of the memory controller 110.

The SRAM 113 may be used as a buffer memory, a cache memory, or an operational memory of the memory controller 110.

The ROM 114 may store various types of information required for the operation of the memory controller 110 in the form of firmware.

The host interface circuit 115 may provide interfacing between the external device and the memory controller 110. For example, the host interface circuit 115 may be provided based on at least one of communication protocols such as universal serial bus (USB), multimedia card (MMC), embedded-MMC, peripheral component interconnection (PCI), PCI express, advanced technology attachment (ATA), serial-ATA, parallel-ATA, small computer system interface (SCSI), enhanced small disk interface (ESDI), integrated drive electronics (IDE), Firewire, universal flash storage (UFS), nonvolatile memory express (NVMe), or compute express link (CXL).

The memory interface circuit 116 may provide interfacing between the memory device 120 and the memory controller 110.

In an example embodiment, the reliability defense manager 111 and/or the flash translation layer 103 may be stored in the SRAM 113 and may be driven (e.g., executed) by the processor 112.

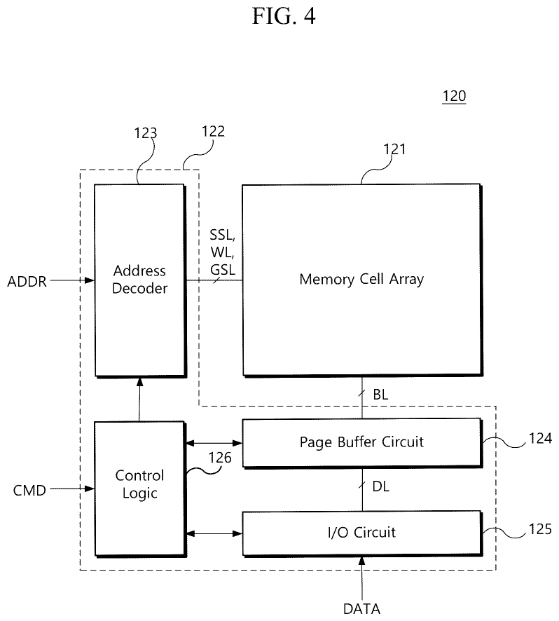

FIG. 4 is a block diagram illustrating an example of the memory device 120 of FIG. 1.

Referring to FIGS. 1 and 4, the memory device 120 may include a memory cell array 121 and a peripheral circuit 122, and the peripheral circuit 122 may include an address decoder 123, a page buffer circuit 124, an input/output (I/O) circuit 125, and a control logic 126.

The memory cell array 121 may include a plurality of blocks, as discussed with reference to FIG. 1. Each of the plurality of blocks may include a plurality of strings. Each of the plurality of strings may include a plurality of memory cells, and each of the plurality of memory cells may be connected to a plurality of wordlines WL. In addition, each of the plurality of blocks may include a plurality of sub-blocks, as discussed with reference to FIG. 1. According to an example embodiment, each of the plurality of sub-blocks may have a different size.

The address decoder 123 may be connected to the memory cell array 121 via a plurality of wordlines WL, string select lines SSL, and ground select lines GSL. The address decoder 123 may receive an address ADDR from the memory controller 110 and decode the received address ADDR. The address decoder 123 may select at least one of the plurality of wordlines WL based on the decoded address ADDR.

The page buffer circuit 124 may be connected to the memory cell array 121 via a plurality of bitlines BL. The page buffer circuit 124 may be connected to the I/O circuit 125 via a plurality of data lines DL. The page buffer circuit 124 may control the plurality of bitlines BL such that the received data DATA is written in the memory cell array 121 via the plurality of data lines DL. The page buffer circuit 124 may detect a change in voltage of the plurality of bitlines BL to read the data stored in the memory cell array 121, and provide the read data to the I/O circuit 125 via the plurality of data lines DL.

The I/O circuit 125 may exchange data DATA with the memory controller 110.

The control logic 126 may receive a command CMD from the memory controller 110 and control the overall operation of the memory device 120 in response to the received command CMD.

In an example embodiment, when a command for a reliability defense operation is received from the memory controller 110, the control logic 126 may control the memory device 120 to perform the reliability defense operation. In an example embodiment, the control logic 126 may control the memory device 120 to perform the reliability defense operation in units of sub-blocks or super sub-blocks. Accordingly, the performance of the reliability defense operation may be improved, when compared to related memory devices.

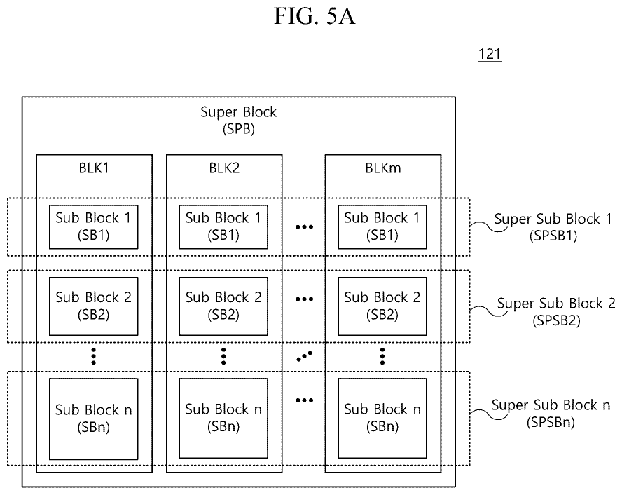

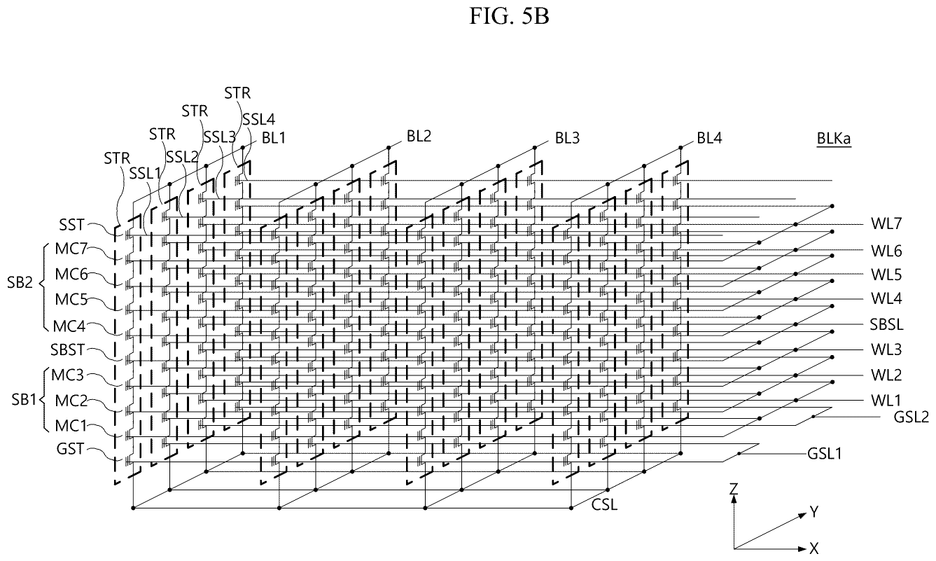

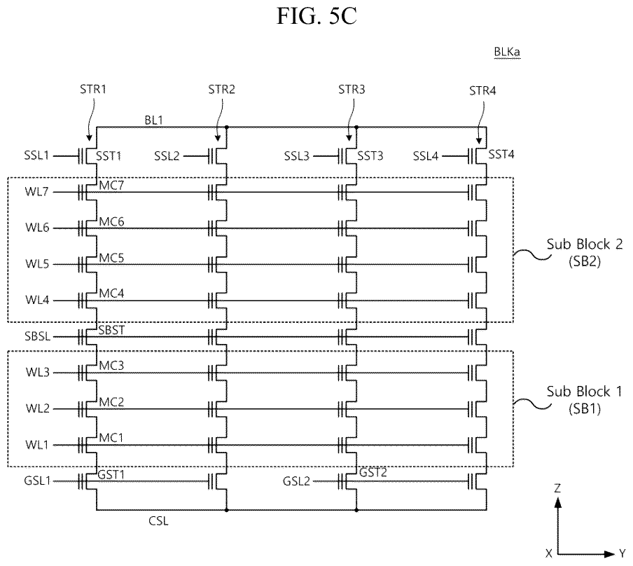

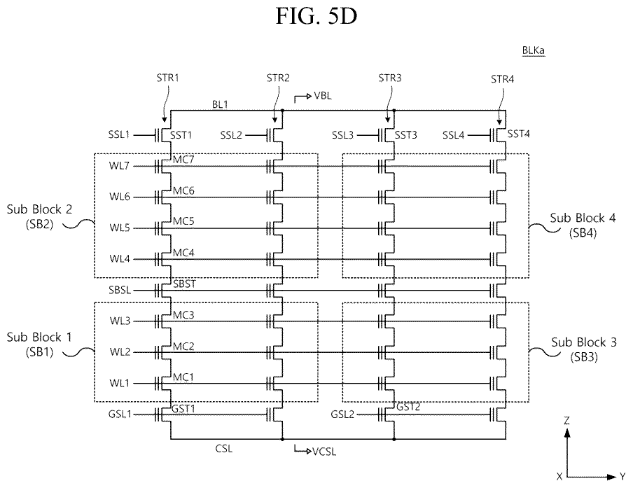

FIGS. 5A to 5D are diagrams illustrating examples of a super block, a block, a super sub-block, and a sub-block included in the memory cell array 121 of FIG. 4.

FIG. 5A illustrates an example of a single super block, among super blocks included in the memory cell array 121.

Referring to FIG. 5A, a super block SPB may include a plurality of blocks BLK1 to BLKm. In an example embodiment, each of the plurality of blocks BLK1 to BLKm may be implemented to have the same physical size.

Each of the plurality of blocks BLK1 to BLKm may include a plurality of sub-blocks SB1 to SBn. According to an example embodiment, each of the plurality of sub-blocks SB1 to SBn may be implemented or set to have a different size.

In an example embodiment, each of the plurality of sub-blocks SB1 to SBn may have a different size. For example, the first sub-block SB1 and the second sub-block SB2 may be implemented to have different physical sizes. In an example embodiment, the first sub-block SB1 may be dynamically allocated to have a first size, and the second sub-block SB2 may be dynamically allocated to have a second size, different from the first size.

In an example embodiment, a portion of the plurality of sub-blocks SB1 to SBn may have different sizes, and a portion thereof may have the same size. For example, the size of the first sub-block SB1 may be the same as a size of the second sub-block SB2, and may be different from a size of a third sub-block.

According to an example embodiment, the size of each of the plurality of sub-blocks SB1 to SBn may be the same.

Each of the plurality of super sub-blocks SPSB1 to SPSBn may include a plurality of sub-blocks.

In an example embodiment, the sub-blocks included in the same super sub-block may have the same size.

For example, the first super sub-block SPSB1 may include the first sub-blocks SB1 of the first to m-th blocks BLK1 to BLKm. The first sub-blocks SB1, constituting the first super sub-block SPSB1, may all have the same size. The second super sub-block SPSB2 may include the second sub-blocks SB2 of the first to m-th blocks BLK1 to BLKm. The second sub-blocks SB2, constituting the second super sub-block SPSB2, may all have the same size.

In an example embodiment, sub-blocks included in different super sub-blocks may have different sizes.

For example, a size of the first sub-block SB1 constituting the first super sub-block SPSB1 and a size of the second sub-block SB2 constituting the second super sub-block SPSB2 may be different from each other.

FIG. 5B illustrates an example of a single block BLKa, from among the plurality of blocks BLK1 to BLKm of FIG. 4.

Referring to FIG. 5B, a plurality of strings STR may be disposed in rows and columns on a substrate. The plurality of strings STR may be commonly connected to a common source line CSL formed on (or in) the substrate.

Referring to FIG. 5B, the common source line CSL is illustrated as being connected to a lower ends of the strings STR. However, the common source line CSL may only need to be electrically connected to the lower ends of the strings STR, and is not limited to being physically located on the lower ends of the strings STR. For example, in FIG. 5B, the strings STR are illustrated as being arranged in a 4×4 array, however, the present disclosure is not limited in this regard, and the block BLKa may include a smaller or larger number of strings.

Strings in each row may be commonly connected to a ground select line (e.g., a first ground select line GSLI or a second ground select line GSL2). For example, strings in first and second rows may be commonly connected to the first ground select line GSL1, and strings in third and fourth rows may be commonly connected to the second ground select line GSL2. However, this is only an example, and four (4) different ground select lines may be provided and strings in each row may be implemented to be connected to different ground select lines.

Strings in each row may be connected to corresponding string select lines, from among a plurality of string select lines (e.g., a first string select line SSL1, a second string select line SSL2, a third string select line SSL3, and a fourth string select line SSL4). Cell strings in each column may be connected to a corresponding bitline from among a plurality of bitlines (e.g., a first bitline BL1, a second bitline BL2, a third bitline BL3, and a fourth bitline BL4).

Each string may include at least one ground select transistor GST connected to the ground select line (e.g., the first ground select line GSL1 or the second ground select line GSL2), a plurality of memory cells (e.g., a first memory cell MC1, a second memory cell MC2, a third memory cell MC3, a fourth memory cell MC4, a fifth memory cell MC5, a sixth memory cell MC6, and a seventh memory cell MC7) respectively connected to a plurality of word lines (e.g., a first word line WL1, a second word line WL2, a third word line WL3, a fourth word line WL4, a fifth word line WL5, a sixth word line WL6, and a seventh word line WL7), and string select transistors SSTs respectively connected to the string select lines (e.g., the first string select line SSL1, the second string select line SSL2, the string select line SSL3, and the string select line SSL4). In addition, each string may include sub-block separation transistors SBSTs, each connected to a sub-block separation line SBSL.

In each string, the ground select transistor GST, the plurality of memory cells MC1 to MC7, the sub-block separation transistors SBST, and the string select transistors SST may be connected in series in a direction perpendicular to the substrate, and may be sequentially adapted in the direction perpendicular to the substrate.

The sub-block separation transistors SBSTs, according to an example embodiment, may be arranged in various locations.

In an example embodiment, the sub-block separation transistors SBST may be disposed at a location defined such that a size of the first sub-block SB1 is smaller than a size of the second sub-block SB2.

For example, as illustrated in FIG. 5B, the sub-block separation transistors SBST may be disposed between the third memory cell MC3 and the fourth memory cell MC4. In an example embodiment, the first to third memory cells MC1 to MC3 may be disposed below the sub-block separation transistors SBST, and the fourth to seventh memory cells MC4 to MC7 may be disposed above the sub-block separation transistors SBST. The first to third memory cells MC1 to MC3 disposed below the sub-block separation transistors SBST may be referred to as the first sub-block SB1, and the fourth to seventh memory cells MC4 to MC7 disposed above the sub-block separation transistors SBST may be referred to as the second sub-block SB2. A size of the first sub-block SB1 may be smaller than a size of the second sub-block SB2.

Alternatively or additionally, in an example embodiment, the sub-block separation transistors SBSTs may be disposed at a location defined such that the size of the first sub-block SB1 is larger than the size of the second sub-block SB2.

For example, the sub-block separation transistors STST may be disposed between the fourth memory cell MC4 and the fifth memory cell MC5. In an example embodiment, the first to fourth memory cells MC1 to MC4 disposed below the sub-block separation transistors SBST may be referred to as the first sub-block SB1, and the fifth to seventh memory cells MC5 to MC7 arranged above the sub-block separation transistors SBST may be referred to as the second sub-block SB2.

Alternatively or additionally, in an example embodiment, the sub-block separation transistors STST may be disposed at a location defined such that the size of the first sub-block SB1 is the same as the size of the second sub-block SB2.

The sub-block separation transistors SBSTs according to an example embodiment may be allocated or formed in various ways.

In an example embodiment, at least one of the plurality of transistors included in the string STR formed on the substrate may be allocated as a sub-block separation transistor SBST. In an example embodiment, the sub-block separation transistors SBSTs may be dynamically allocated, and thus the sizes of the first sub-block SB1 and the second sub-block SB2 may be set to vary depending on use mode.

Alternatively or additionally, in an example embodiment, the sub-block separation transistors SBST may be formed to be physically separated from memory cells. For example, the sub-block separation transistors SBST may be formed as N-channel metal oxide semiconductor (NMOS) transistors that do not have a charge trapping layer between a channel and a gate, unlike the memory cells.

Alternatively or additionally, in an example embodiment, a channel structure constituting strings STR formed on the substrate may include a lower channel structure lower channel structure and an upper channel structure upper channel structure, and the lower channel structure and the upper channel structure may be formed using different processes.

For example, when the memory device 120 is formed in a chip-on-peri (COP) structure, a diameter of an upper end of the lower channel structure may be larger than a diameter of a lower end of the upper channel structure. For example, when the memory device 120 is formed in a chip-to-chip (C2C) structure, the diameter of the upper end of the lower channel structure may be smaller than the diameter of the lower end of the upper channel structure.

In a structure in which the channel structure includes a lower channel structure and an upper channel structure, at least one of the wordlines located near a boundary between the lower channel structure and the upper channel structure may be referred to as a sub-block separation line SBSL, and the memory cells connected to the sub-block separation line SBSL may be referred to as sub-block separation transistors SBST.

In an example embodiment, the sub-block separation line SBSL may be disposed on the upper end of the lower channel structure. For example, the first and second ground select lines GSL1 and GSL2, the first to third wordlines WL1 to WL3, and the sub-block separation line SBSL correspond to a lower channel structure of each string STR, and the fourth to seventh wordlines WL4 to WL7 and the string select lines SSL1 to SSL4 may correspond to an upper channel structure of each string STR.

Alternatively or additionally, in an example embodiment, the sub-block separation line SBSL may be disposed on the lower end of the upper channel structure. For example, the first and second ground select lines GSL1 and GSL2 and the first to third wordlines WL1 to WL3 may correspond to a lower channel structure of each string STR, and the sub-block separation line SBSL, the fourth to seventh wordlines WL4 to WL7, and the first to fourth string select lines SSL1 to SSL4 may correspond to an upper channel structure of each string STR.

Alternatively or additionally, in an example embodiment, a wordline disposed on the upper end of the lower channel structure may be set as a first sub-channel select line, and a wordline disposed on a lower end of the upper channel structure may be set as a second sub-channel select line.

Alternatively or additionally, in an example embodiment, the sub-channels may be distinguished by biasing a dummy wordline rather than setting a specific-purpose string select transistor. For example, in a string STR including a lower channel structure and an upper channel structure, at least one of the wordlines disposed near a boundary between the lower channel structure and the upper channel structure may be set as a dummy wordline, and the first sub-block SB1 and the second sub-block SB2 may be distinguished by biasing the dummy wordline.

FIG. 5C illustrates an example of a block BLKa that may be divided into a first sub-block SB1 and a second sub-block SB2 by a sub-block separation line SBSL. For ease of description, FIG. 5C illustrates an example in which first to fourth strings STR1 to STR4 are connected to a first bitline BL1. An example is provided in which the sub-block separation line SBSL is disposed between a third wordline WL3 and a fourth wordline WL4.

Referring to FIG. 5C, the block BLKa may include first and second sub-blocks SB1 and SB2 and may perform an erase operation in units of sub-blocks.

For example, during an erase operation on the first sub-block SB1, an erase voltage (e.g., 22V) may be provided through a common source line CSL and a voltage lower than the erase voltage (e.g., 16V) may be provided through first and second ground select lines GSL1 and GSL2. In addition, a ground voltage may be provided through the first bitline BL1, and a ground voltage may be provided through the first to fourth string select lines SSL1 to SSL4. In an example embodiment, the sub-block separation transistors SBSTs may be set to a non-conducting state. Accordingly, an erase operation may be performed on the first sub-block SB1.

For example, during an erase operation on the second sub-block SB2, an erase voltage (e.g., 22 Volts (V)) may be provided through the first bitline BLI and a voltage lower than the erase voltage (e.g., 16 V) may be provided through the first to fourth string select lines SSL1 to SSL4. In addition, a ground voltage may be provided through the common source line CSL, and a ground voltage may be provided through the first and second ground select lines GSL1 and GSL2. In an example embodiment, the sub-block separation transistors SBST may be set to a non-conducting state. Accordingly, an erase operation may be performed on the second sub-block SB2.

As described above, the block BLKa may be divided into the first sub-block SB1 and the second sub-block SB2, and erase operations may be performed on a sub-block unit. In addition, as described below, according to an example embodiment, a reliability defense operation may be performed in units of sub-blocks or super sub-block units.

FIG. 5D illustrates an example of a block BLKa that may be divided into the first to fourth sub-blocks SB1 to SB4 by a sub-block separation line SBSL, string select lines SSL1 to SSL4, and first and second ground select lines GSL1 and GSL2. For ease of description, similarly to FIG. 5C, FIG. 5D illustrates an example in which first to fourth strings STR1 to STR4 are connected to the first bitline BL1. In addition, an example is provided in which the sub-block separation line SBSL is disposed between a third wordline WL3 and a fourth wordline WL4.

Referring to FIG. 5D, the block BLKa may include first to fourth sub-blocks SB1 to SB4 and may perform erase operation in units of sub-blocks.

For example, during an erase operation on the first sub-block SB1, an erase voltage (e.g., 22 V) may be provided through a common source line CSL, a voltage lower than the erase voltage (e.g., 16 V) may be provided through the first ground select line GSL1, and a ground voltage is provided through the second ground select line GSL2. In addition, a ground voltage may be provided through the first bitline BL1, and a ground voltage may be provided through the first to fourth string select lines SSL1 to SSL4. In an example embodiment, the sub-block separation transistors SBST may be set to a non-conducting state. Accordingly, an erase operation may be performed on the first sub-block SB1.

For example, during an erase operation on the second sub-block SB2, an erase voltage (e.g., 22V) may be provided through the first bitline BL1, a voltage lower than the erase voltage (e.g., 16V) may be provided through the first and second string select lines SSL1 and SSL2, and a ground voltage may be provided through the third and fourth string select lines SSL3 and SSL4. In addition, a ground voltage may be provided through the common source line CSL, and a ground voltage may be provided through the first and second ground select lines GSL1 and GSL2. In an example embodiment, the sub-block separation transistors SBST may be set to a non-conducting state. Accordingly, an erase operation may be performed on the second sub-block SB2.

For example, during an erase operation on the third sub-block SB3, an erase voltage (e.g., 22 V) may be provided through the common source line CSL, a voltage lower than the erase voltage (e.g., 16 V) may be provided through the second ground select line GSL2, and a ground voltage may be provided through the first ground select line GSL1. In addition, a ground voltage may be provided through the first bitline BL1, and a ground voltage may be provided through the first to fourth string select lines SSL1 to SSL4. In an example embodiment, the sub-block separation transistors SBST may be set to a non-conducting state. Accordingly, an erase operation may be performed on the third sub-block SB3.

For example, during an erase operation on the fourth sub-block SB4, an erase voltage (e.g., 22 V) may be provided through the first bitline BL1, a voltage lower than the erase voltage (e.g., 16 V) may be provided through the third and fourth string select lines SSL3, SSL4, and a ground voltage may be provided through the first and second string select lines SSL1 and SSL2. In addition, a ground voltage may be provided through the common source line CSL, and a ground voltage may be provided through the first and second ground select lines GSL1 and GSL2. In an example embodiment, the sub-block separation transistors SBSTs may be set to a non-conducting state. Accordingly, an erase operation may be performed on the fourth sub-block SB4.

As described above, the block BLKa may be divided into the first to fourth sub-blocks SB1 to SB4, and erase operations may be performed in units of sub-blocks. In addition, as described below, according to an example embodiment, a reliability defense operation may be performed in units of sub-blocks or super sub-blocks.

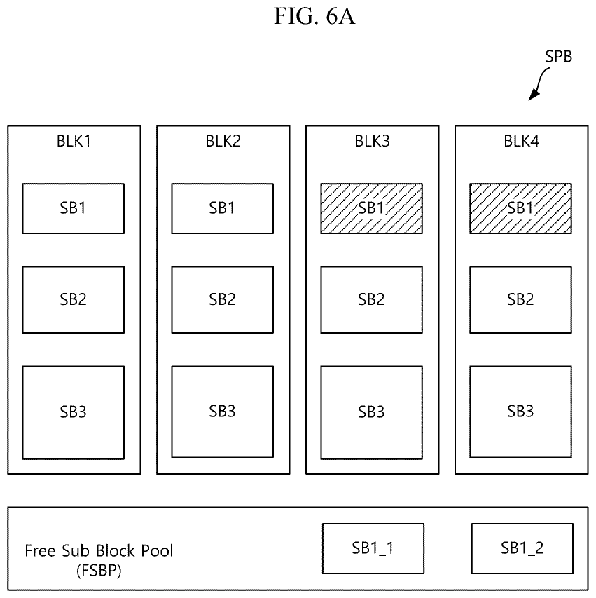

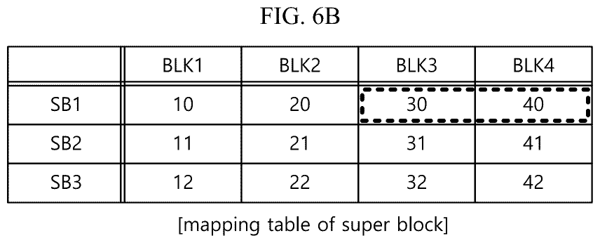

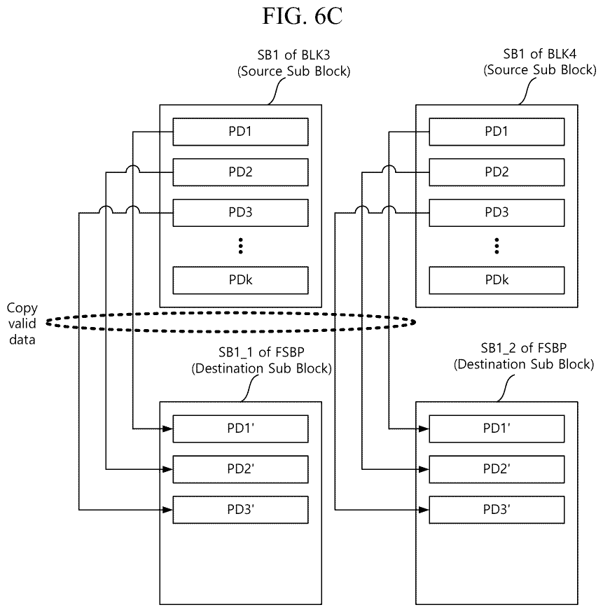

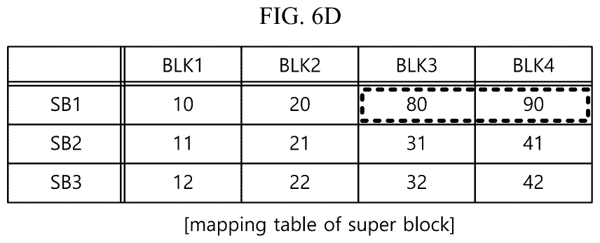

FIGS. 6A to 6D are diagrams illustrating a read reclaim operation, according to an example embodiment. FIG. 6A illustrates an example in which read disturbance occurs. FIG. 6B illustrates an example of a mapping table of a super block when read disturb occurs. FIG. 6C illustrates an example of an operation in which valid data is copied in a read reclaim operation. FIG. 6D illustrates an example of an operation in which a mapping table of a super block is updated in a read reclaim operation.

For ease of description, an example is provided in which a super block SPB includes first to fourth blocks BLK1 to BLK4, and each of the first to fourth blocks BLK1 to BLK4 includes first to third sub-blocks SB1 to SB3. An example is also provided in which, among the first to third sub-blocks SB1 to SB3, the first sub-block SB1 has a smallest size and the third sub-block SB3 has a largest size.

In addition, for ease of description, an example is provided in which a physical address of the first sub-block SB1 of the third block BLK3 is ‘30,’ a physical address of the first sub-block SB1 of the fourth block BLK4 is ‘40,’ a physical address of a 1_1-th sub-block SB1_1 of a free sub-block pool FSBP is ‘80,’ and a physical address of a 1_2-th sub-block SB1_2 of the free sub-block pool FSBP is ‘90.’

Referring to FIGS. 6A and 6B, data stored in a specific page of a super block SPB may include a number of error bits greater than or equal to a reference number. For example, due to frequent read operations and/or read disturbance (disturb) on a specific page, data stored in the specific page may include a number of error bits greater than or equal to a reference number. In an example embodiment, a read reclaim operation may be requested to prevent errors from being uncorrectable by an error control code (ECC) operation.

For example, as shown in FIG. 6A, data stored in the first sub-block SB1 of the third block BLK3 and the first sub-block SB1 of the fourth block BLK4 may include a number of error bits greater than or equal to a reference number. Additionally, for example, as illustrated in FIG. 6B, a physical address of the first sub-block SB1 of the third block BLK3, in which read disturb has occurred, may be ‘30’ and a physical address of the first sub-block SB1 of the fourth block BLK4 may be ‘40.’

In an example embodiment, the reliability defense manager 111, according to an example embodiment, may perform a read reclaim operation using the 1_1-th sub-block SB1_1 and the 1_2-th sub-block SB1_2 of the free sub-block pool FSBP. For example, sizes of the first_1 sub-block SB1_1 and the first_2 sub-block SB1_2 may each be the same as a size of the first sub-block SB1 for which the read reclaim operation is requested.

To put it in more detail with reference to FIGS. 6C and 6D, the memory device 120 (see referring to FIG. 1) according to an example embodiment may perform a read reclaim operation on the first sub-block SB1 of the third block BLK3 and the first sub-block SB1 of the fourth block BLK4 in response to the control of the reliability defense manager 111.

For example, as illustrated in FIG. 6C, the memory device 120 may set the first sub-block SB1 of the third block BLK3, for which the read reclaim operation is requested, as a source sub-block and set the 1_1-th sub-block SB1_1 of the free sub-block pool FSBP as a destination sub-block.

The memory device 120 may perform an operation of copying first page data to third page data PD1 to PD3, valid data stored in the first sub-block of the third block BLK3, to the 1_1-th sub-block SB1_1, a destination sub-block.

In an embodiment, the memory device 120 may perform an operation of copying the first data PD1 to the third page data PD3, which are valid data stored in the first sub-block SB1 of the third block BLK3 that is a source sub-block, to the 1_1-th sub-block SB1_1 that is a destination sub-block.

In an example embodiment, the copy operation may include an operation of reading the valid data stored in the source sub-block and an operation of programming the read valid data back into the destination source block. Accordingly, first page data to third page data PD1′ to PD3′ restored in the 1_1-th sub-block SB1_1 may be data having a sufficient read margin.

Alternatively, according to an example embodiment, an error correction operation on the data stored in the first page data to the third page data PD1 to PD3 may be performed together. Therefore, the first page data to the third page data PD1′ to PD3′ restored in the 1_1-th sub-block SB1_1 may be error-corrected data having a sufficient read margin.

Similarly, the memory device 120 may set the first sub-block SB1 of the fourth block BLK4, for which the read reclaim operation is requested, as a source sub-block and set the first_2 sub-block SB1_2 of the free sub-block pool FSBP as a destination sub-block.

The memory device 120 may perform an operation of copying the first page data to the third page data PD1 to PD3, which are valid data stored in the first sub-block SB1 of the fourth block BLK4 that is a source sub-block, to the 1_2-th sub-block SB1_2 that is a destination sub-block.

After the copy operation, the reliability defense manager 111 according to an example embodiment may update a mapping table of a super block.

For example, as illustrated in FIG. 6D, the reliability defense manager 111 may update the mapping table of the super block stored in the SRAM 113. As another example, the reliability defense manager 111 may update a physical address of the first sub-block SB1 of the third block BLK3 constituting the super block SPB to ‘80’ and update a physical address of the first sub-block SB1 of the fourth block BLK4 to ‘90.’

Accordingly, when a read request for the data stored in the first sub-block SB1 of the third block BLK3 is issued, the data PD1′ to PD3′ stored in the sub-block SB1_1 corresponding to the physical address ‘80’ may be read. Similarly, when a read request for the data stored in the first sub-block SB1 of the fourth block BLK4 is issued, the data PD1′ to PD3′ stored in the sub-block SB1_2 corresponding to the physical address ‘90’ may be read.

As described in FIGS. 6A to 6D, the memory device 120 according to an example embodiment may perform a read reclaim operation in units of sub-blocks. Accordingly, the read reclaim operation may be efficiently performed, when compared to related memory devices.

For example, a related memory device may perform a read reclaim operation in units of blocks. In an example embodiment, all valid data stored in a source block may be copied to a destination block. For example, the larger the size of the source block, the more valid data is stored. Accordingly, the number of read and program operations that may need to be performed during the copy operation may also increase. As a result, the performance of read reclaim may deteriorate, and may also cause an increase in time required to perform the read reclaim.

Alternatively, the memory device 120, according to an example embodiment, may divide a block into a plurality of sub-blocks and may perform a read reclaim operation in units of sub-blocks. Accordingly, only the valid data stored in the source sub-block may be copied to a destination sub-block, so that the number of read and program operations that should be performed during the copy operation may be decreased. As a result, the memory device 120 according to an example embodiment may provide a read reclaim operation having improved performance, when compared to the related memory devices.

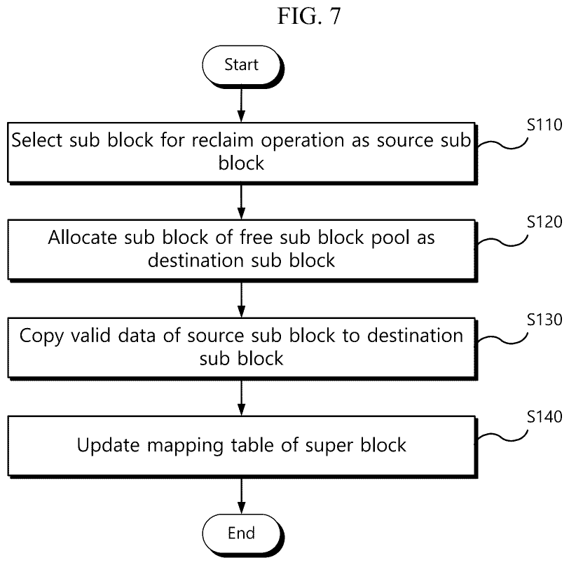

FIG. 7 is a flowchart illustrating a read reclaim operation, according to an example embodiment.

In operation S110, a sub-block for which a read reclaim operation is requested may be selected as a source sub-block.

For example, the memory device 120 may select a sub-block, containing a number of error bits greater than or equal to a reference number, as a source sub-block in response to a request from the reliability defense manager 111.

In operation S120, a sub-block of the free sub-block pool FSBP may be allocated as a destination sub-block.

For example, the memory device 120 may allocate a sub-block having the same size as the source sub-block in the free sub-block pool FSBP as a destination sub-block. However, the present disclosure is not limited in this regard, and, according to example embodiments, the memory device 120 may allocate a sub-block larger than the source sub-block in the free sub-block pool FSBP as a destination sub-block.

In operation S130, valid data of the source sub-block may be copied to the destination sub-block.

For example, the memory device 120 may read the valid data, stored in a page of the source sub-block, and program the read data in the destination sub-block. In an example embodiment, error correction may be performed on the read data, and error-corrected data may be programmed in the destination sub-block.

In operation S140, the mapping table of the super block may be updated.

For example, the reliability defense manager 111 may update the mapping table of the super block to read data stored in the destination source block when a read request is issued.

As described above, the read reclaim operation according to an example embodiment may be performed in units of sub-blocks. As a result, the read reclaim operation may be efficiently performed, when compared to related memory devices.

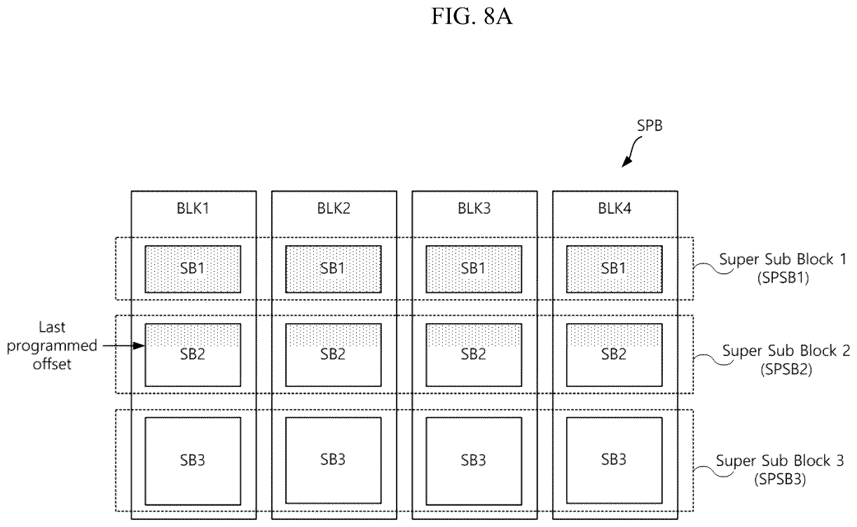

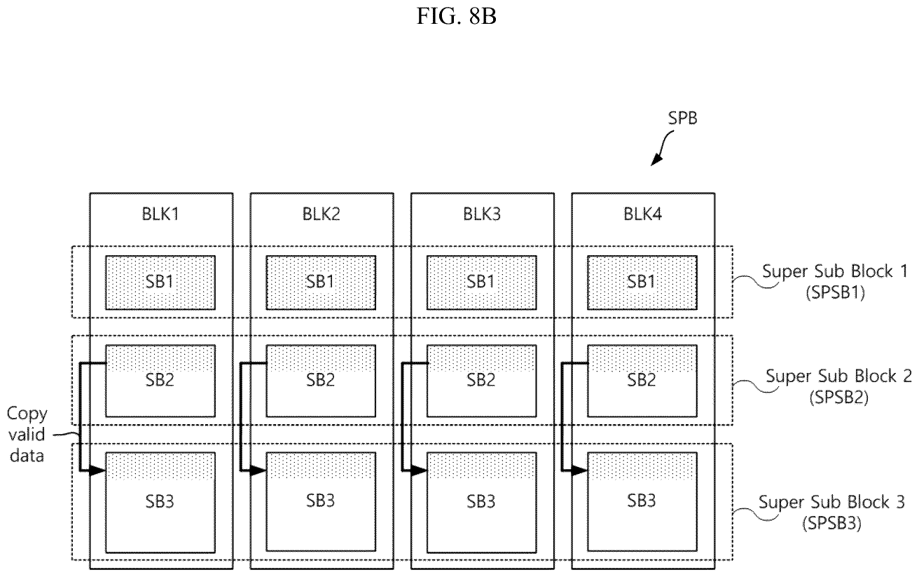

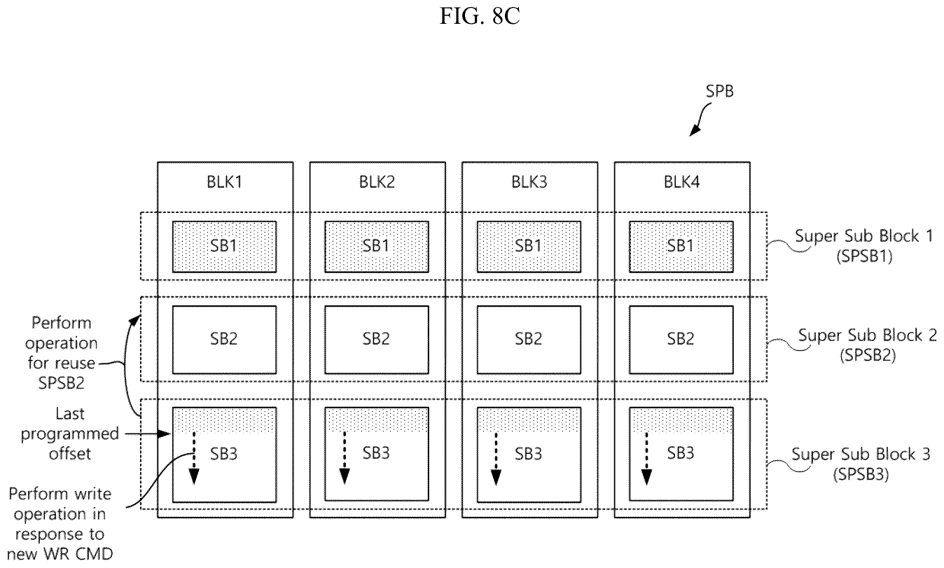

FIGS. 8A to 8C are diagrams illustrating an active reclaim operation, according to an example embodiment. FIGS. 8A to 8C illustrate an example in which an active reclaim operation is performed using an empty sub-block within a super block SPB.

FIG. 8A illustrates an example in which a write operation is stopped due to an exceptional situation such as sudden power-off (SPO) occurring during a write operation. FIG. 8B illustrates an example of an operation of copying valid data in an active reclaim operation. FIG. 8C illustrates an example of a processing operation on a source super sub-block and a destination super sub-block after the copy operation is performed.

Hereinafter, for ease of description, an example is provided in which a super block SPB includes first to fourth blocks BLK1 to BLK4, and each of the first to fourth blocks BLK1 to BLK4 includes first to third sub-blocks SB1 to SB3. An example is also provided in which, among the first to third sub-blocks SB1 to SB3, the first sub-block SB1 has a smallest size and the third sub-block SB3 has a largest size. An example is also provided in which active reclaim by SPO is requested during a write operation on a second super sub-block SPSB2.

Referring to FIG. 8A, the super block SPB may include first to fourth blocks BLK1 to BLK4, and each of the first to fourth blocks BLK1 to BLK4 may include first to fourth sub-blocks SB1 to SB3. The first sub-blocks SB1 of the first to fourth blocks BLK1 to BLK4 may constitute a first super sub-block SPSB1, the second sub-blocks SB2 of the first to fourth blocks BLK1 to BLK4 may constitute a second super sub-block SPSB2, and the third sub-blocks SB3 of the first to fourth blocks BLK1 to BLK4 may constitute a third super sub-block SPSB3.

A write operation may be performed in units of super blocks SPB. For example, operations of programming data in the first to fourth blocks BLK1 to BLK4 included in the super block SPB may be simultaneously performed.

During a write operation performed in units of super blocks SPB, the memory device 120 may be powered off by SPO. When the memory device 120 is powered on again, an active reclaim operation of moving valid data, programmed before the occurrence of SPO, to a safe storage location may be requested to safely manage the valid data.

In an example embodiment, the reliability defense manager 111, according to an example embodiment, may control the memory device 120 to perform an active reclaim operation in units of super sub-blocks. For example, as illustrated in FIG. 8A, when there are no remaining empty sub-blocks that may be set as a destination super sub-block within the super block SPB, the reliability defense manager 111 may perform an active reclaim operation using the empty sub-blocks within the super block SPB.

That is, as described with reference to FIGS. 8B and 8C, the memory device 120, according to an example embodiment, may perform an active reclaim operation on the second super sub-block SPSB2 in response to the control of the reliability defense manager 111.

For example, as illustrated in FIG. 8B, the memory device 120 may set the second super sub-block SPSB2, for which an active reclaim operation is requested, as a source super sub-block and an empty third super sub-block SPSB3 within the same super block SPB may be set as a destination super sub-block.

The memory device 120 may perform an operation of copying valid data stored in the second super sub-block SPSB2, a source super sub-block, to the third super sub-block SPSB3, a destination super sub-block.

After the copy operation, the memory device 120, according to an example embodiment, may perform a treatment for reuse of the source super sub-block.

For example, as illustrated in FIG. 8C, the memory device 120 may perform an erase operation on the second super sub-block SPSB2. Accordingly, the second super sub-block SPSB2 may be changed to an empty state in which data is re-storable.

After the active reclaim operation is performed, a continuous write operation may be requested by an external device. In an example embodiment, the memory device 120, according to an example embodiment, may continuously (e.g., repeatedly, periodically and/or aperiodically) perform a write operation on the third super sub-block SPSB3.

As described above, the memory device 120, according to an example embodiment, may perform an active reclaim operation in units of super sub-blocks. For example, the memory device 120, according to an example embodiment, may perform an active reclaim operation using empty sub-blocks within the super block SPB.

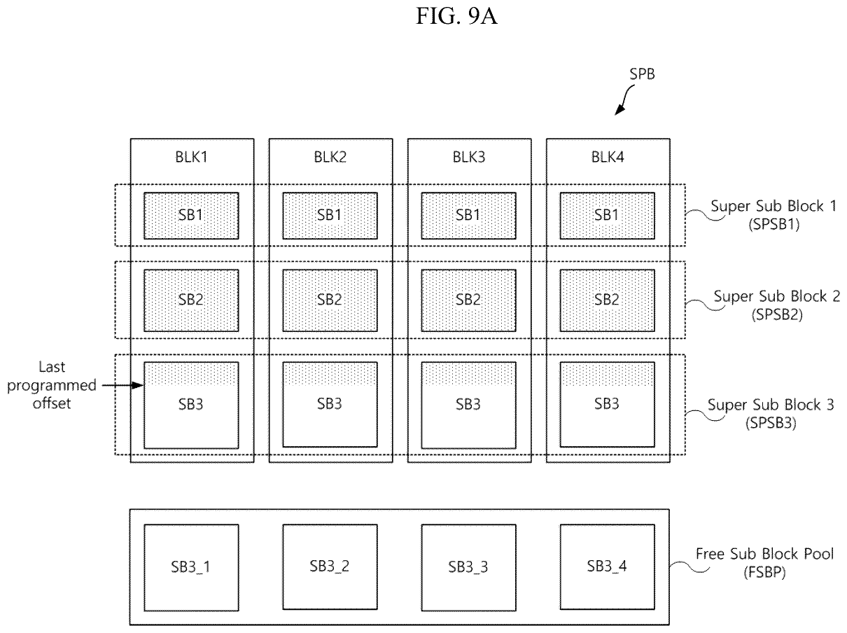

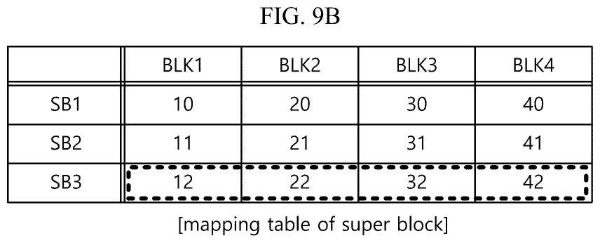

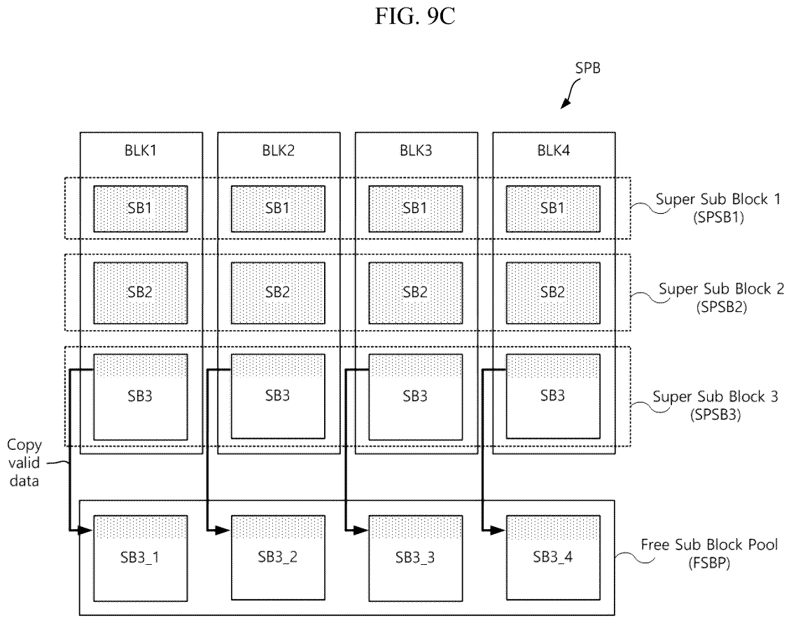

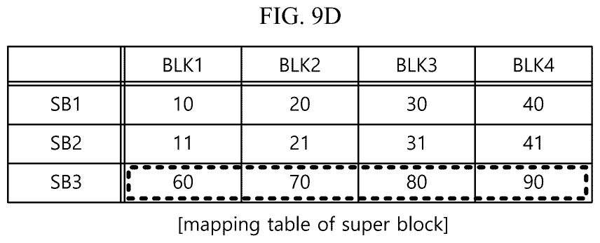

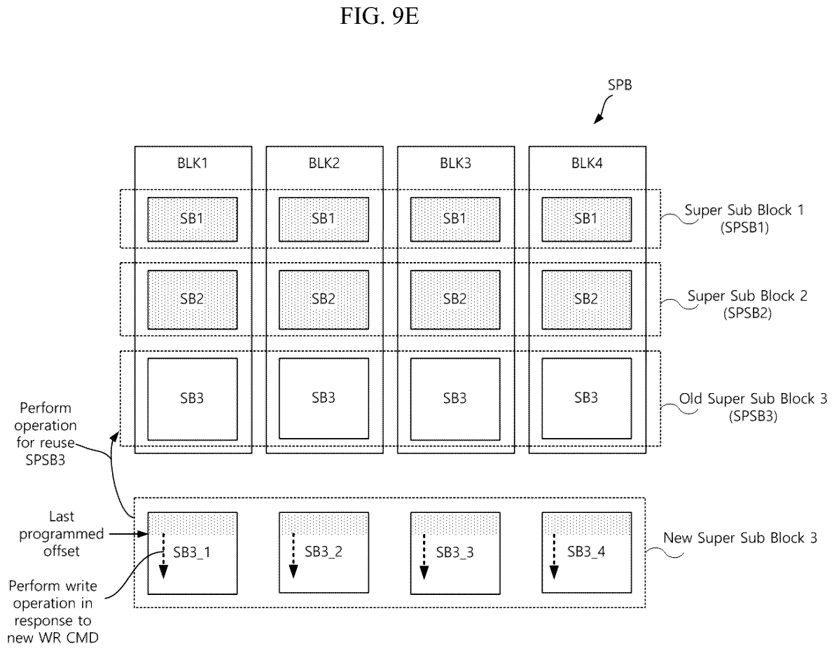

FIGS. 9A to 9E are diagrams illustrating an active reclaim operation, according to an example embodiment. FIGS. 9A to 9E illustrate an example of performing an active reclaim operation using a free sub-block pool FSBP outside a super block SPB.

FIG. 9A illustrates an example in which a write operation is stopped due to an exceptional situation such as SPO during a write operation. FIG. 9B illustrates an example of a mapping table of a super block when SPO occurs. FIG. 9C illustrates an example of an operation in which valid data is copied in an active reclaim operation. FIG. 9D illustrates an example of an operation in which a mapping table of a super block is updated in an active reclaim operation. FIG. 9E illustrates an example of a processing operation on a source super sub-block and a destination super sub-block after the copy operation is performed.

Similarly to FIG. 8A, an example is provided in which a super block SPB includes first to fourth blocks BLK1 to BLK4, and each of the first to fourth blocks BLK1 to BLK4 includes first to third sub-blocks SB1 to SB3. An example is also provided in which, among the first to third sub-blocks SB1 to SB3, the first sub-block SB1 has a smallest size and the third sub-block SB3 has a largest size. For ease of description, an example is also provided in which active reclaim by SPO is requested during a write operation on the third super sub-block SPSB3.

Referring to FIGS. 9A and 9B, the memory device 120 may be powered off by SPO during a write operation performed in units of super blocks SPB. When the memory device 120 is powered on again, an active reclaim operation may be requested to move valid data, programmed before the occurrence of SPO, to another storage location.

For example, when there are no remaining empty sub-blocks that may be set as a destination super sub-block within the super block SPB, the reliability defense manager 111, according to an example embodiment, may perform an active reclaim operation using a free sub-block pool FSBP.

For example, as illustrated in FIG. 9A, SPO may occur during a write operation on the third super sub-block SPSB3. As another example, as illustrated in FIG. 9B, physical addresses of the third sub-blocks SB3 of the third super sub-block SPSB3, in which SPO has occurred, may be ‘12,’ ‘22,’ ‘32,’ and ‘42,’ respectively.

In an example embodiment, the reliability defense manager 111, according to an example embodiment, may perform an active reclaim operation using the third_1 to third_4 sub-blocks SB3_1 to SB3_4 of the free sub-block pool FSBP. For example, each of the third_1 to third_4 sub-blocks SB3_1 to SB3_4 may have the same size as each of the third sub-block SB3 for which the active reclaim operation is requested.

That is, as described with reference to FIGS. 9C and 9D, the memory device 120, according to an example embodiment, may perform an active reclaim operation on the third super sub-block SPSB3 in response to the control of the reliability defense manager 111.

For example, as illustrated in FIG. 9C, the memory device 120 may set the third super sub-block SPSB3, for which an active reclaim operation is requested, as a source super sub-block and set the third_1 to third_4 sub-blocks SB3_1 to SB3_4 of the free sub-block pool FSBP as a destination super sub-block.

Then, the memory device 120 may perform an operation of copying valid data stored in the third super sub-block SPSB3, a source super sub-block, to 3_1-th to 3_4-th sub-blocks SB3_1 to SB3_4, destination super sub-blocks.

After the copy operation, the reliability defense manager 111, according to an example embodiment, may update a mapping table of a super block.

For example, as illustrated in FIG. 9D, the reliability defense manager 111 may update the mapping table of the super block stored in the SRAM 113. As another example, the reliability defense manager 111 may update physical addresses of the third sub-blocks SB3 of the first to fourth blocks BLK1 to BLK4, constituting the third super sub-block SPSB3, to ‘60,’ ‘70,’ ‘80,’ and ‘90’, respectively.

After the mapping table of the super block is updated, the memory device 120, according to an example embodiment, may perform a process for reuse of the source super sub-block.

For example, as illustrated in FIG. 9E, the memory device 120 may perform an erase operation on the third super sub-block SPSB3. Accordingly, the third super sub-block SPSB3 may be changed to an empty state in which data is re-storable.

After the active reclaim operation is performed, a continuous write operation may be requested by an external device. In an example embodiment, the memory device 120 according to an example embodiment may continuously perform the write operation on 3_1-th to 4_4-th sub-blocks SB3_1 to SB3_4, new third super sub-blocks.

As described above, the memory device 120, according to an example embodiment, may perform an active reclaim operation in units of super sub-blocks. For example, the memory device 120 may perform an active reclaim operation using the sub-blocks of the free sub-block pool FSBP.

As described in FIGS. 8A to 9E, the memory device 120, according to an example embodiment, may perform an active reclaim operation in unis of super sub-blocks.

In the case of a typical memory device, an active reclaim operation is performed in units of blocks. In an example embodiment, all valid data stored in a block in which SPO occurred should be copied to a destination block. Accordingly, as the size of a block increases, the performance of active reclaim is likely to be degraded.

The memory device 120, according to an example embodiment, may divide a block into a plurality of sub-blocks and perform an active reclaim operation in units of sub-blocks. Accordingly, only the valid data stored in the source sub-block may be copied to the destination sub-block, so that the number of read and program operations that should be performed during the copy operation may decrease. As a result, the memory device 120, according to an example embodiment, may provide an active reclaim operation having improved performance, when compared to related memory devices.

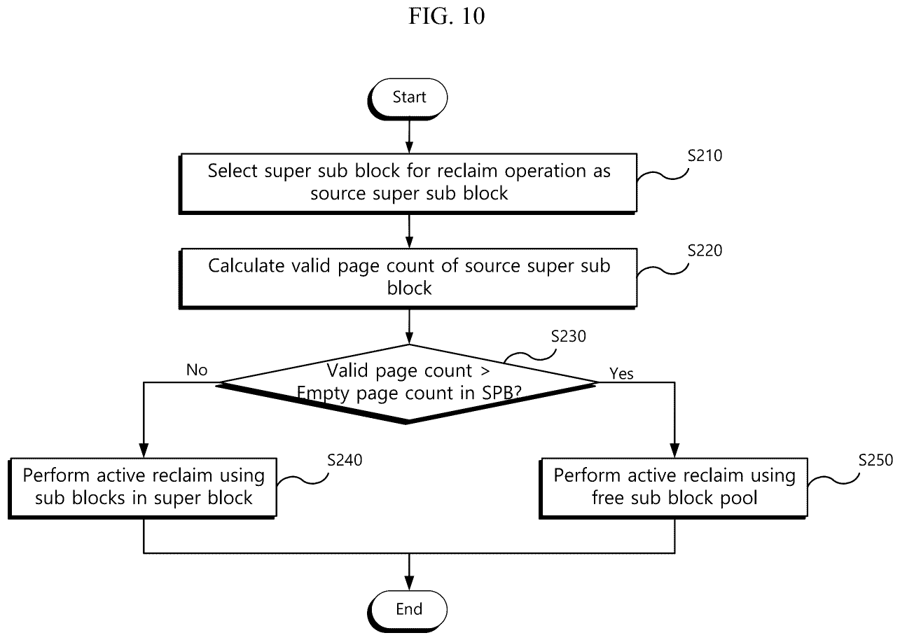

FIG. 10 is a flowchart illustrating an active reclaim operation, according to an example embodiment.

In operation S210, a sub-block for which an active reclaim operation is requested may be selected as a source sub-block.

For example, the memory device 120 may select the super sub-block, in which SPO has occurred, as the source super sub-block in response to a request from the reliability defense manager 111.

In operation S220, a valid page count of the source super sub-block may be calculated.

For example, the reliability defense manager 111 may count the number of pages, storing valid data, within the super sub-block in which SPO occurred.

In operation S230, a determination may be made as to whether the count of valid pages is greater than a count of empty pages within the super block SPB.

When the count of valid pages is less than the count of empty pages within the super block SPB (No in operation S230), the flow proceeds to operation S240 in which an active reclaim operation may be performed using the empty sub-blocks within the super block SPB.

When the count of valid pages is greater than the count of empty pages within the super block SPB (Yes in operation S230), the flow proceeds to operation S250 in which the active reclaim operation may be performed using the sub-blocks of the free sub-block pool FSBP.

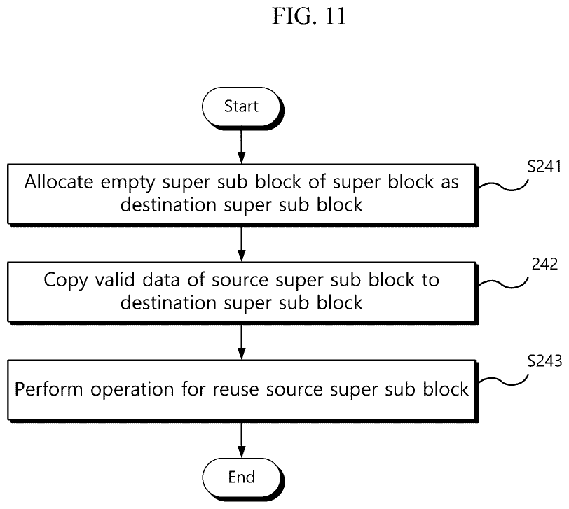

FIG. 11 is a flowchart illustrating an example embodiment in which an active reclaim operation is performed using sub-blocks within a super block.

In operation S241, a super sub-block within a super block may be allocated as a destination super sub-block.

For example, the memory device 120 may allocate a super sub-block including a sub-block having the same size as a sub-block within the source super sub-block, among empty super sub-blocks within the super block, as a destination super sub-block.

In operation S242, valid data of the source super sub-block may be copied to the destination super sub-block.

For example, the memory device 120 may read the valid data stored in the pages of the source super sub-block, and may program the read data in the destination super sub-block. In an example embodiment, error correction may be performed on the read data, and the error-corrected data may be programmed in the destination sub-block.

In operation S243, an operation for reuse of the super sub-block, in which SPO has occurred, may be performed.

For example, the memory device 120 may perform an erase operation on the super sub-block in which the SPO has occurred. Accordingly, each of the sub-blocks of the super sub-block, in which the SPO has occurred, may be changed to an empty sub-block.

As described above, the active reclaim operation according to an example embodiment may be performed in units of super sub-blocks. For example, the active reclaim operation may be performed using the sub-blocks within the super block. Accordingly, the active reclaim operation may be efficiently performed, when compared to a related memory device.

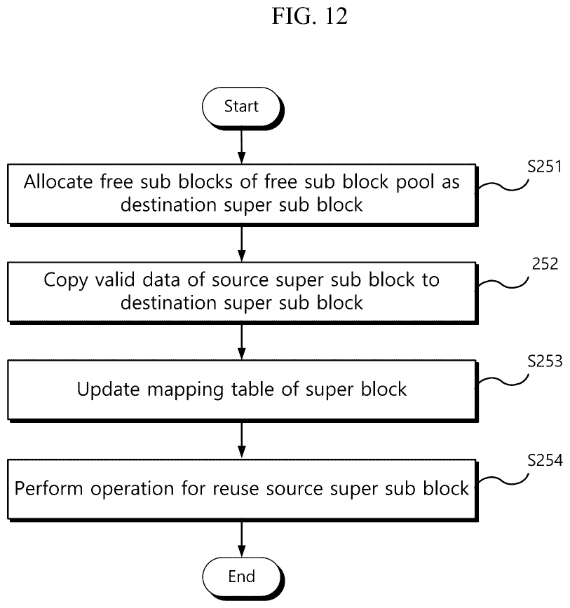

FIG. 12 is a flowchart illustrating an example embodiment in which an active reclaim operation is performed using a free sub-block pool.

In operation S251, a super sub-block of a free sub-block pool may be allocated as a destination super sub-block.

For example, the memory device 120 may allocate sub-blocks having the same size as a sub-block in a source super sub-block in the free sub-block pool as the destination super sub-block.

In operation S252, valid data of the source super sub-block may be copied to the destination super sub-block.

In operation S253, a mapping table of the super block may be updated.

For example, the reliability defense manager 111 may update the mapping table of the super block such that data may be programmed in the destination source block when a continuous write request is issued.

In operation S254, an operation for reuse of the super sub-block, in which SPO has occurred, may be performed.

For example, the memory device 120 may perform an erase operation on the super sub-block in which the SPO has occurred. Accordingly, each of the sub-blocks of the super sub-block, in which the SPO has occurred, may be changed to an empty sub-block.

As described above, the active reclaim operation according to an example embodiment may be performed in units of super sub-blocks. For example, the active reclaim operation may be performed using sub-blocks within the free sub-block pool. Accordingly, the active reclaim operation may be efficiently performed, when compared to a related memory device.

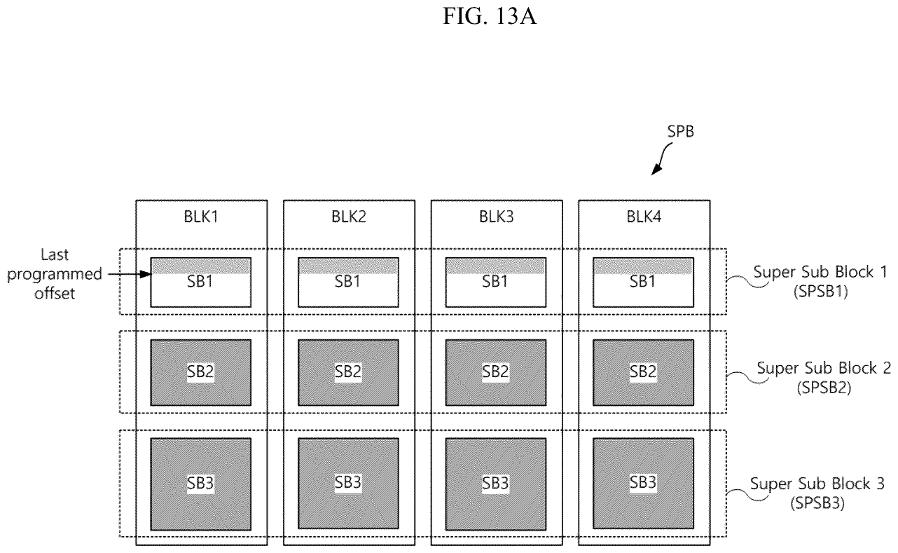

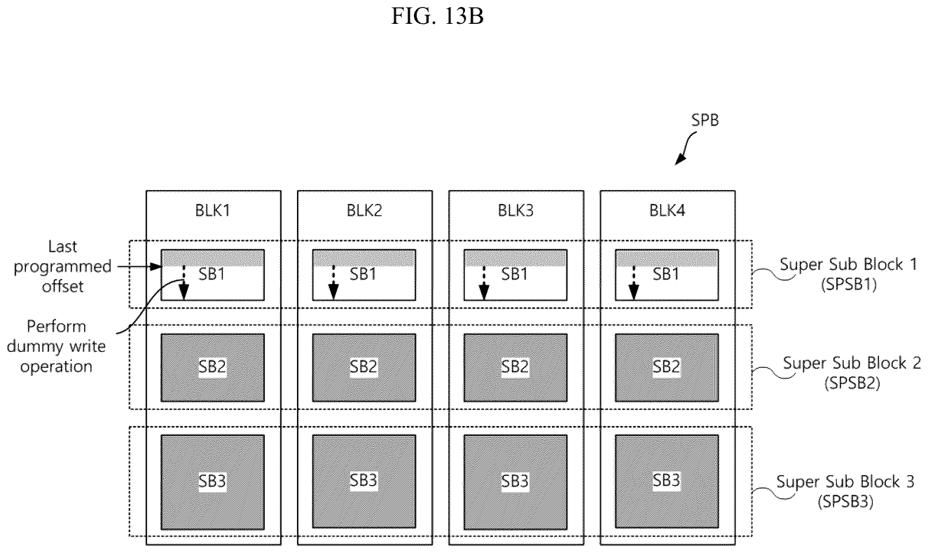

FIGS. 13A and 13B are diagrams illustrating a dummy program operation, according to an example embodiment. FIG. 13A illustrates an example of a super block SPB including valid data, and FIG. 13B illustrates an example in which a dummy program operation is performed to reuse a super sub-block including invalid data.

For ease of description, an example is provided in which a super block SPB includes first to fourth blocks BLK1 to BLK4, and each of the first to fourth blocks BLK1 to BLK4 includes first to third sub-blocks SB1 to SB3. An example is also provided in which, among the first to third sub-blocks SB1 to SB3, the first sub-block SB1 has a smallest size and the third sub-block SB3 has a largest size. For ease of description, an example is also provided in which a first super sub-block SPSB1 includes pages including invalid data and an empty page.

Referring to FIGS. 13A and 13B, an erase operation should be performed to reuse a super sub-block including invalid data.

For example, as illustrated in FIG. 13A, an erase operation should be performed on a first super sub-block SPSB1 to reuse the first super sub-block SPSB1.

In an example embodiment, the first super sub-block SPSB1 includes empty pages, so that an erase operation may be re-performed on even pages in an erase state when the erase operation is performed without dummy program. As a result, a program-erase interval EPI may deviate from a predetermined interval, which may cause a decrease in reliability and life of the first super sub-block SPSB1.

Accordingly, to maintain the program-erase interval EPI within a predetermined interval, the memory device 120, according to an example embodiment, may perform a dummy program operation before performing an erase operation.

For example, as illustrated in FIG. 13B, a dummy program operation may be performed on the first super sub-block SPSB1, and an erase operation may then be performed on the first super sub-block SPSB1. Accordingly, the program-erase interval EPI may be maintained within a predetermined interval.

When the dummy program operation is performed in units of blocks, the dummy program operation should be performed on all empty pages, which may increase the number of dummy program operations and the execution time. The memory device 120, according to an example embodiment, may perform a dummy program operation in units of super sub-blocks, which may decrease the number of dummy program operations and the execution time. As a result, the memory device 120 according to an example embodiment may efficiently perform the dummy program operation, when compared to a related memory device.

According to an example embodiment, the dummy program operation described in FIGS. 13A and 13B may be applied to a process for reuse of the super sub-block described in FIGS. 8C and 9C.

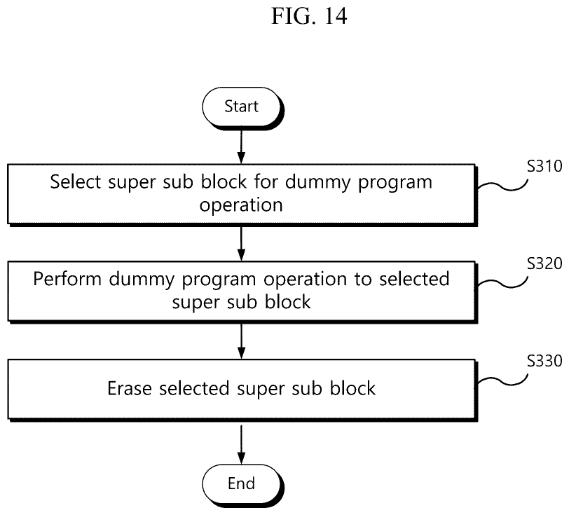

FIG. 14 is a flowchart illustrating an operation of performing a process for reuse of a super sub-block according to an example embodiment.

In operation S310, a super sub-block on which a dummy program operation is to be performed may be selected.

For example, a super sub-block including pages including invalid data and empty pages may be selected as the super sub-block on which the dummy program operation is to be performed.

In operation S320, a dummy program operation may be performed on the selected super sub-block. Accordingly, data may be stored in all pages of the selected super sub-block.

In operation S330, an erase operation may be performed on the selected super sub-block. Accordingly, the selected super sub-block may be changed to a reusable super sub-block while maintaining the program-erase interval within a predetermined interval.

As described above, the dummy program operation according to an example embodiment may be performed in units of super sub-blocks. Thus, the dummy program operation may be effectively performed, when compared to a related memory device.

As set forth above, a memory system according to example embodiments may provide a reliability defense operation with improved reliability.

While example embodiments have been shown and described above, it is to be apparent to those skilled in the art that modifications and variations may be made without departing from the scope of the present disclosure as defined by the appended claims.

What is claimed is:

1. A memory system comprising:
a memory device comprising a plurality of blocks; and
a memory controller configured to control the memory device;
wherein the plurality of blocks comprise:
a first block comprising a first sub-block having a first size and a second sub-block having a second size different from the first size; and
a second block comprising a third sub-block having a third size and a fourth sub-block having a fourth size different from the third size,
wherein the first size of the first sub-block is equal to the third size of the third sub-block,
wherein the first sub-block and the third sub-block constitute a first super sub-block,
wherein the second size of the second sub-block is equal to the fourth size of the fourth sub-block,
wherein the second sub-block and the fourth sub-block constitute a second super sub-block, and
wherein the memory controller is further configured to perform a reliability protection operation on the memory device in units of sub-blocks or super sub-blocks.

2. The memory system of claim 1, further comprising:
a free sub-block pool comprising a fifth sub-block having a fifth size,
wherein the fifth size of the fifth sub-block is equal to the first size of the first sub-block,
wherein the memory device is configured to:
copy valid data, stored in the first sub-block, to the fifth sub-block based on a number of error bits in data stored in the first sub-block being greater than or equal to a number of reference bits.

3. The memory system of claim 2, wherein the memory controller comprises a mapping table managing first addresses of sub-blocks included in the first super sub-block and second addresses of sub-blocks included in the second super sub-block, and
wherein the memory controller is further configured to:
change a first physical address corresponding to data stored in the first sub-block to a second physical address of the fifth sub-block after the valid data stored in the first sub-block is copied to the fifth sub-block.

4. The memory system of claim 2, wherein the memory device is further configured to:
read the valid data stored in the first sub-block;
perform an error correction operation on the read valid data; and
program the error-corrected data in the fifth sub-block based on the number of error bits in data stored in the first sub-block being greater than or equal to the number of reference bits.

5. The memory system of claim 1, wherein the first size of the first sub-block and the third size of the third sub-block included in the first super sub-block are less than or equal to the second size of the second sub-block and the fourth size of the fourth sub-block included in the second super sub-block, and
wherein the memory device is configured to:
copy valid data stored in the first super sub-block to the second super sub-block based on an active reclaim request for the first super sub-block being issued.

6. The memory system of claim 5, wherein the memory device is further configured to:
perform an erase operation on the first super sub-block after the valid data stored in the first super sub-block is copied to the second super sub-block.

7. The memory system of claim 6, wherein the memory device is further configured to:
perform a dummy program operation on the first super sub-block before performing the erase operation on the first super sub-block.

8. The memory system of claim 1, further comprising:
a free sub-block pool comprising a fifth sub-block having a fifth size and a sixth sub-block having a sixth size,
wherein the fifth size of the fifth sub-block and the sixth size of the sixth sub-block are equal to the first size of the first sub-block and the third size of the third sub-block included in the first super sub-block,
wherein the memory device is further configured, based on an active reclaim request for the first super sub-block being issued, to:
copy first valid data stored in the first sub-block to the fifth sub-block; and
copy second valid data stored in the third sub-block to the sixth sub-block.

9. The memory system of claim 8, wherein the memory controller comprises a mapping table managing first addresses of sub-blocks included in the first super sub-block and second addresses of sub-blocks included in the second super sub-block, and
wherein the memory controller is further configured to:
change a first physical address corresponding to data stored in the first sub-block to a second physical address of the fifth sub-block and a third physical address corresponding to data stored in the third sub-block to a fourth physical address of the sixth sub-block after the first valid data stored in the first sub-block and the second valid data stored in the third sub-block are respectively copied to the fifth sub-block and the sixth sub-block.

10. The memory system of claim 8, wherein the memory device is further configured to:
perform a first erase operation on the first super sub-block after the first valid data stored in the first sub-block is copied to the fifth sub-block; and
perform a second erase operation on the first super sub-block after the second valid data stored in the third sub-block is copied to the sixth sub-block.

11. The memory system of claim 6, wherein the memory device is further configured to:
perform a dummy program operation on the first super sub-block before performing the erase operation on the first super sub-block.

12. The memory system of claim 1, wherein each of the plurality of blocks comprises a plurality of memory cells, vertically stacked on a substrate,
wherein the first sub-block and the second sub-block included in the first block are separated by a first sub-block separation line disposed at a first height with respect to the substrate, and
wherein the third sub-block and the fourth sub-block included in the second block are separated by a second sub-block separation line disposed at a same height as the first sub-block separation line.

13. The memory system of claim 12, wherein each of the first block and the second block comprises a lower channel structure, vertically formed on the substrate, and an upper channel structure formed on the lower channel structure,
wherein the first sub-block separation line is disposed in a first boundary region between the lower channel structure and the upper channel structure of the first block, and
wherein the second sub-block separation line is disposed in a second boundary region between the lower channel structure and the upper channel structure of the second block.

14. A memory device comprising:
a memory cell array comprising a plurality of blocks storing data; and
a control logic configured to control the memory cell array,
wherein the plurality of blocks comprise:
a first block comprising a first sub-block having a first size and a second sub-block having a second size different from the first size; and
a second block comprising a third sub-block having a third size and a fourth sub-block having a fourth size different from a size of the third sub-block,
wherein the first size of the first sub-block is equal to the third size of the third sub-block,
wherein the first sub-block and the third sub-block constitute a first super sub-block,
wherein the second size of the second sub-block is equal to the fourth size of the fourth sub-block,
wherein the second sub-block and the fourth sub-block constitute a second super sub-block, and
wherein the control logic is further configured to:
control the memory cell array to perform at least one of a read reclaim operation, an active reclaim operation, or a dummy program operation in units of sub-blocks or super sub-blocks.

15. The memory device of claim 14, wherein the memory cell array comprises a free sub-block pool comprising a fifth sub-block having a fifth size,
wherein the fifth size of the fifth sub-block is equal to the first size of the first sub-block, and
wherein the control logic is configured to:
copy valid data, stored in the first sub-block, to the fifth sub-block based on a number of error bits in data stored in the first sub-block being greater than or equal to a number of reference bits.

16. The memory device of claim 14, wherein the first size of the first sub-block and the third size of the third sub-block included in the first super sub-block are less than or equal to the second size of the second sub-block and the fourth size of the fourth sub-block included in the second super sub-block, and
wherein the control logic is configured to:
copy valid data stored in the first super sub-block to the second super sub-block based on an active reclaim request for the first super sub-block being issued.

17. The memory device of claim 16, wherein the control logic is further configured to:
sequentially perform the dummy program operation and an erase operation on the first super sub-block after the valid data stored in the first super sub-block is copied to the second super sub-block.

18. The memory device of claim 14, wherein the memory cell array comprises a free sub-block pool comprising a fifth sub-block having a fifth size and a sixth sub-block having a sixth size,
wherein the fifth size of the fifth sub-block and the sixth size of the sixth sub-block are equal to the first size of the first sub-block and the third size of the third sub-block included in the first super sub-block, and
wherein the control logic is further configured, based on an active reclaim request for the first super sub-block being issued, to:
copy first valid data stored in the first sub-block to the fifth sub-block; and
copy second valid data stored in the third sub-block to the sixth sub-block.

19. The memory device of claim 18, wherein the control logic is configured to:
sequentially perform the dummy program operation and an erase operation on the first super sub-block after the first valid data stored in the first sub-block and the second valid data stored in the third sub-block are respectively copied to the fifth sub-block and the sixth sub-block.

20. A method of operating a memory system comprising a plurality of blocks, the method comprising:
selecting a first sub-block for which a reclaim operation is requested, from among sub-blocks included in each of the plurality of blocks, as a source sub-block;
allocating a second sub-block having a same size as the source sub-block and being in an empty state, from among the sub-blocks included in each of the plurality of blocks, as a destination sub-block; and
moving valid data stored in the source sub-block to the destination sub-block in units of sub-blocks.
